(19) United States
(12) Patent Application Publication
(10) Pub. No.: US 2009/0167314 A1
(43) Pub. Date: Jul. 2, 2009

(54) Method and Device for Detecting Ground Faults in a Supply Cable

(75) Inventor: Reinhard Hoffmann, Erlangen (DE)

Correspondence Address: LERNER GREENBERG STEMER LLP, P O BOX 2480, HOLLYWOOD, FL, 33022-2480, US

(73) Assignee: SIEMENS AKTIENGESELLSCHAFT, Munich (DE)

(21) Appl. No.: 12/278,667

(22) PCT Filed: Feb. 2, 2007
(86) PCT No.: PCT/EP2007/051012

§ 371 Date: Aug. 7, 2008

(30) Foreign Application Priority Data
Feb. 7, 2006 (DE) 10 2006 006 350.3

(51) Int. Cl. G01R 31/14

(52) U.S. Cl. 324/509

(57) ABSTRACT

A method for detecting a ground fault of a multi-phase energy supply cable carrying alternating current includes determining an average potential of the energy supply cable, entering the average potential or a variable derived therefrom into an evaluation unit, and comparing the average potential or the variable derived from the average potential with a threshold value in the evaluation unit. Ground faults are detected reliably and less expensively by presuming a ground fault if the comparison indicates that the value of the average potential or the variable derived therefrom has fallen below the threshold.

The invention relates to a method for determining a ground fault in a polyphase alternating-current-conducting power supply cable, in which a star point potential of the power supply cable is determined, a variable derived from the star point potential or the star point potential itself is supplied to an evaluation unit, and the evaluation unit compares the star point potential or the variable derived from the star point potential with a threshold value.

The invention also relates to an apparatus for supplying power to a load with a power-feeding inverter, which is connected to the load via a polyphase power supply cable, and means for determining a star point potential of the power supply cable, which means are connected to an evaluation unit.

Such a method and such an apparatus are already known from the common prior art. It has therefore become conventional, for example in the field of high-voltage surge arresters, to detect the current flowing via the respective phase of a multi-element power supply line and to add up the individual phase currents to give a total current. In the fault-free state, the total current calculated in this way is equal to zero. In the event of a fault, on the other hand, some of the current flows away via ground, with the result that the individual phase currents no longer add up to zero. If, therefore, the total current exceeds a predetermined threshold value, an evaluation unit which detects the fault event triggers necessary protective measures.

The offprint from ZEVrail Glasers Annalen, special edition “Transrapid 2003” entitled “Antrieb und Energieversorgung des Transrapid” [“Drive and power supply of the Transrapid”] by Blank, Engel, Hellinger, Hoke and Nothaft, page 17, diagram 23 discloses a method in which the voltage of a polyphase alternating-current-conducting power supply cable is measured, the zero voltage criterion being used as proof of a ground fault.

In the case of the Transrapid, ground faults in particular in the feed cables of the motor sections of the stator but also in the motor windings themselves need to be detected in a reliable manner. In this case, the ground faults need to be disconnected within a predetermined time window, with the result that possible development into a short circuit or risk to personnel as a result of excessively high step voltages or voltage overloads of the power transmission systems are avoided. The development of the ground fault into a two-pole ground fault can result in a short circuit, as a result of which the vehicle can lose its poise for a short period of time.

One problem with the ground fault detection in the motor sections of the Transrapid is the detection of a ground fault in the vicinity of the system neutral point. However, increased importance is attached to this region. A further disadvantage with this ground fault detection is that a broad and varying spectrum of interference voltage frequencies is produced by converters feeding power. The interference voltage frequencies impede the reliable ground fault detection, however.

The object of the invention is to provide a method and an apparatus of the type mentioned at the outset with which ground faults can be detected in a reliable and inexpensive manner.

The invention achieves this object on the basis of the method mentioned at the outset by virtue of the fact that the threshold value being undershot indicates a ground fault.

The invention achieves this object on the basis of the apparatus mentioned at the outset by virtue of the fact that the evaluation unit is designed to identify a ground fault as a function of a DC voltage shift.

According to the invention, a star point potential which is applied or is in any case present is used to safely indicate a ground fault. This is geared to the fact that such a star point potential is eliminated in the event of a ground fault. According to the invention, the symmetrical loading of a polyphase power supply line is therefore not monitored as in the case of the previously known method and apparatus. Instead, the fault identification according to the invention is geared to the directly or indirectly detected cancellation of the star point potential.

In accordance with an advantageous development of the invention, the star point potential is determined via a symmetrical neutral grounding transformer. A neutral grounding transformer comprises, for example, three resistors which are connected in each case to one of the phases of the power supply cable on one side, the resistors being DC-connected to one another on their side remote from the power supply cable, with the result that a neutral point is formed there.

In accordance with a development in this regard, a voltage drop across a load, which is connected between the neutral point of the neutral grounding transformer and the ground potential, is detected whilst obtaining voltage values, and the voltage values are transmitted to the evaluation unit. In this way, the star point potential as such is used, i.e. the star point potential is used directly, as proof of a ground fault. If the star point potential, i.e. the voltage drop across said resistor, undershoots a threshold value which has previously been fixed in the evaluation unit and stored, for example, as a parameter, this indicates the presence of a ground fault.

In accordance with a configuration which is different from this, a current which is flowing between the neutral point of the neutral grounding transformer and the ground potential is detected whilst obtaining current values, and the current values are transmitted to the evaluation unit. The current detection at the neutral point takes place, for example, by means of a calibrated current transformer. If a star point potential is present, a current flow between the neutral point and ground can be proven. This is the case during normal operation. In the event of a ground fault, the star point potential breaks down and the current flow driven by the star point potential then tends towards zero. If the current flow undershoots a threshold value set in the evaluation unit, this can indicate a ground fault.

In accordance with an advantageous development of the apparatus according to the invention, the inverter is connected to the power supply cable via a transformer, additional means for generating a DC voltage shift in the power supply cable being provided. As a result of the fact that the inverter of a power supply cable is connected via a transformer, the DC voltage shift caused by the inverter is lost. For this reason, additional means are required which generate such a DC voltage shift. The additional means for the DC voltage shift can in principle be of any desired design.

In accordance with an advantageous development, however, the additional means for generating a DC voltage shift comprise an asymmetrical passive rectifier circuit at the neutral point of the transformer. Such a passive rectifier circuit is, for example, a series circuit comprising a zener diode and a resistor, said series circuit being arranged between the ground potential and the neutral point of the secondary windings of the transformer.

In accordance with a variant of the invention which is different from this, the additional means for generating a DC voltage shift comprise an asymmetrical active rectifier circuit. Such an active rectifier circuit has, for example, any desired DC voltage source. The DC voltage source can be fed by an AC system or else be in the form of an energy store. Solar cells can also be used in this context. Further possibilities include fuel cells, rechargeable battery units or the like as the energy store.

Further expedient configurations and advantages of the invention are the subject matter of the description below relating to exemplary embodiments of the invention with reference to the figures in the drawing, with identical reference symbols referring to functionally identical component parts. In the drawing:

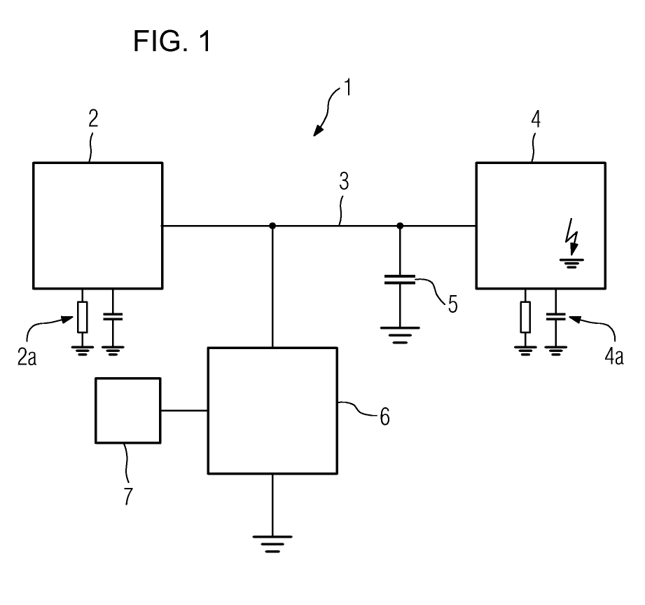

FIG. 1 shows an exemplary embodiment of the apparatus according to the invention in a schematic illustration,

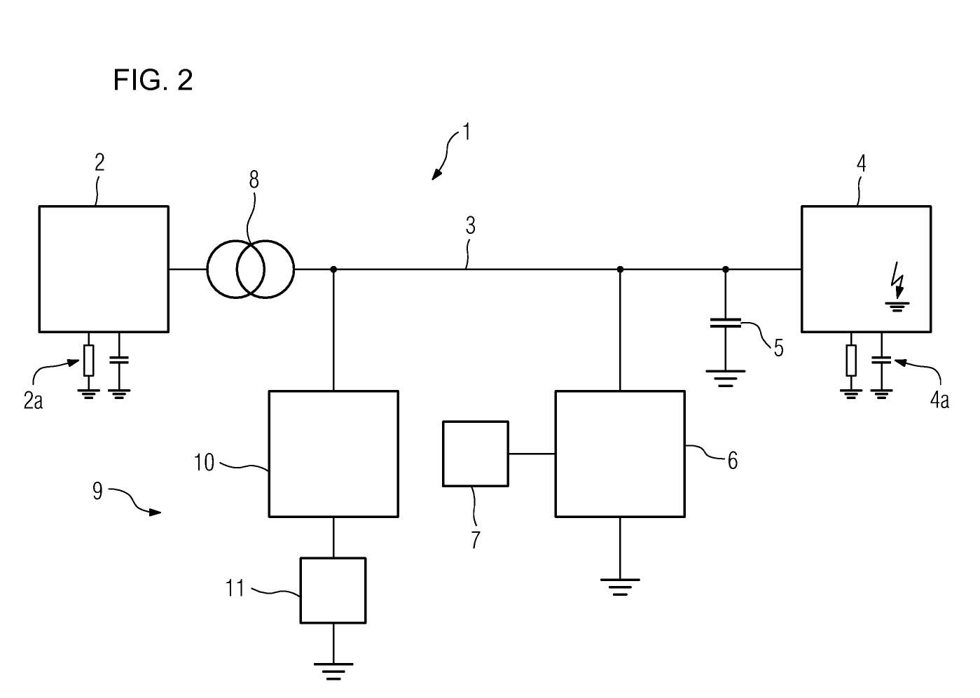

FIG. 2 shows a further exemplary embodiment of the apparatus according to the invention in a schematic illustration,

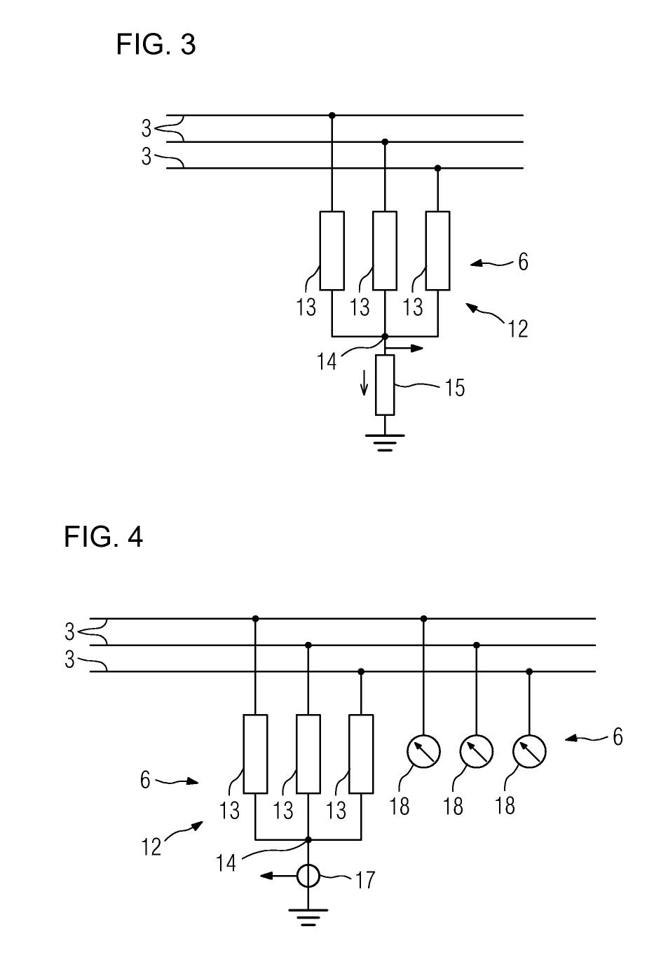

FIG. 3 shows an exemplary embodiment of an additional means for generating a star point potential for detecting a DC voltage shift,

FIG. 4 shows two further exemplary embodiments of an additional means for generating a star point potential for detecting a DC voltage shift,

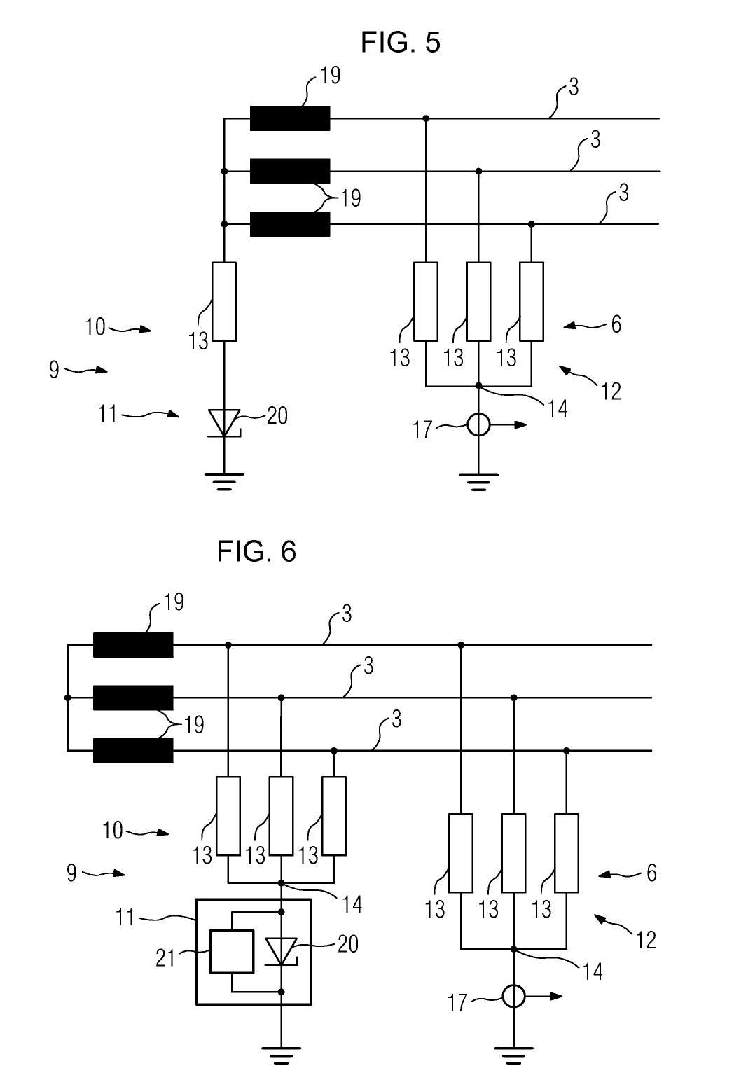

FIG. 5 shows a further exemplary embodiment of an additional means for generating a star point potential for detecting a DC voltage shift, and

FIG. 6 shows a further additional means for generating a DC voltage shift and a neutral grounding transformer.

FIG. 1 shows an exemplary embodiment of the apparatus 1 according to the invention in a schematic illustration. The apparatus 1 shown comprises an inverter 2, which is connected to a load 4 via a polyphase power supply cable 3. The power supply cable 3 has a capacitive ground impedance, which is illustrated schematically by means of the capacitor 5. The coupling impedance 2a of the inverter 2 is illustrated schematically by a grounded capacitor and a resistor connected in parallel therewith. The load impedance 4a is illustrated correspondingly. The coupling impedances 2a of the inverter 2 are coupling impedances which cannot disappear. They are based on the systematic structure of the circuit of the converter, which has freewheeling diodes directed from the negative terminal to the positive terminal. The coupling impedances which cannot disappear of the converter are therefore loaded asymmetrically with respect to ground. In this way, the capacitive ground impedances which is illustrated by the capacitor 5 is precharged on average to a negative DC voltage. The DC voltage charging takes place at a high resistance as a result of the coupling impedances 2a and is independent of the pulse pattern of the inverter 2. The star point potential produced in this way is detected by a detection unit 6 as a means for determining a star point potential and is transmitted to an evaluation unit 7, which, if the star point potential undershoots a predetermined threshold value, triggers a fault message, as a result of which switches and switching units (not illustrated) are triggered.

FIG. 2 shows a further exemplary embodiment of the apparatus 1 according to the invention. The apparatus 1 shown in FIG. 2 differs from apparatus 1 shown in FIG. 1 by virtue of the fact that the inverter 2 is connected to the power supply cable 3 via a transformer 8. For this reason, there is no DC voltage shift brought about by the inverter 2. Additional means 9 for generating a star point potential are therefore provided, which additional means in the exemplary embodiment shown comprise a potential generator 10 and a charging device 11 for the DC voltage shift of the star point potential.

FIG. 3 shows an exemplary embodiment of a detection unit 6. The detection unit 6 has a neutral grounding transformer 12, which comprises three resistors 13 which are connected on the input side to in each case one phase of the power supply cable 3. The resistors 13 are connected to one another on the side remote from the power supply cable 3, with the result that a neutral point 14 is formed. The neutral point 14 is connected to the ground potential via a measuring resistor 15, with the result that, in the event of a DC voltage shift, the star point potential can be tapped off via the measuring resistor 15. This takes place in a conventional manner known to a person skilled in the art. The star point potential detected in this way is then transmitted to the evaluation unit 7 which compares the received star point potential with a threshold value and, in the event of the threshold value being undershot, generates a fault message.

FIG. 4 at the same time shows two further exemplary embodiments of the detection unit 6. In the left-hand part of FIG. 4, again three nonreactive resistors 13 are illustrated which are connected on the input side to in each case one phase of the power supply cable. On the side remote from the power supply cable 3, the resistors 13 are DC-connected to one another, with the result that a neutral point 14 is formed. In contrast to the exemplary embodiment shown in FIG. 3, however, no measuring resistor is provided. Instead, a calibrated current transformer 17 is used for detecting the current driven by the star point potential. In the event of a ground fault, the star point potential breaks down and the driving force for the current flowing to ground therefore collapses, with the result that, in the event of a threshold value being undershot, the evaluation unit 7 generates a fault message.

The right-hand part of FIG. 4 shows a further possible way of generating a star point potential. In this case, three voltmeters 18 are provided which each measure the voltage drop between one phase and the ground potential and transmit the measured value to the evaluation unit 7. The evaluation unit 7 calculates the star point potential from the voltage values communicated to it. If the star point potential falls below a threshold value, a fault procedure is again started.

FIG. 5 shows an exemplary embodiment of the additional means 9 for the DC voltage shift, in which the potential generator 10 is in the form of a nonreactive resistor, which is connected to the neutral point of the secondary windings 19 of the transformer 8. The charging device 11 for the DC voltage shift in the exemplary embodiment shown is realized by a single zener diode 20, which is connected between the nonreactive resistor 13 in the form of a potential generator 10 and the ground potential. As a result of this arrangement, a DC voltage shift is realized. During normal operation, the detection unit 6 therefore detects a permanent direct current.

FIG. 6 shows a further exemplary embodiment of the additional means 9 for generating a DC voltage shift, the potential generator 10 being realized by three resistors 13 which are each connected to one phase of the power supply cable 3. On their side remote from the power supply cable 3, the resistors 13 are connected to one another so as to form a neutral point 14, the neutral point 14 being connected to the ground potential via the charging device 11 for the DC voltage shift. The charging device 11 in this case comprises a zener diode 20 and an active voltage unit 21, which is arranged in parallel with the zener diode 20, for example comprises a solar cell unit, a battery unit or the like. In other words, an active rectifier circuit is provided.

1-13. (canceled)

14. A method for determining a ground fault in a polyphase alternating-current-conducting power supply cable, the method which comprises:
determining a mean potential of the power supply cable is determined and supplying the mean potential or a variable derived from the mean potential to an evaluation unit;
comparing the mean potential or the variable derived from the mean potential with a threshold value in the evaluation unit; and
if the threshold value is undershot, concluding that a ground fault exists.

15. The method according to claim 14, which comprises determining the mean potential via a symmetrical neutral grounding transformer.

16. The method according to claim 15, wherein a load is connected between a neutral point of the neutral grounding transformer and ground potential, and the method comprises detecting a voltage drop across the load and obtaining voltage values, and transmitting the voltage values to the evaluation unit.

17. The method according to claim 15, wherein a load is connected between a neutral point of the neutral grounding transformer and ground potential, and the method comprises detecting a current flowing between the neutral grounding transformer (6) and the ground potential and obtaining current values, and transmitting the current values to the evaluation unit.

18. The method according to claim 14, which comprises measuring an individual potential for each phase of the power supply cable to obtain individual potential values, transmitting the individual potential values of each phase to the evaluation unit, and calculating with the evaluation unit a mean potential on the basis of all of the individual potentials.

19. The method according to claim 14, which comprises impressing a DC voltage component on the power supply cable.

20. The method according to claim 19, which comprises impressing the DC voltage component by way of an asymmetrical active rectifier circuit.

21. The method according to claim 19, which comprises supplying energy to the power supply cable via an inverter.

22. The method according to claim 21, wherein the inverter is connected to the power supply cable via a transformer, and the DC voltage component is impressed at a neutral point of the transformer by way of an asymmetrical passive rectifier circuit.

23. An apparatus for supplying energy to a load, comprising:
a power-feeding inverter connected to the load via a polyphase power supply cable;
means for determining a mean potential of the power supply cable; and
an evaluation unit connected to said means and being configured to identify a ground fault in dependence on a DC voltage shift.

24. The apparatus according to claim 23, which further comprises a transformer connected between said inverter and said power supply cable, and additional means for generating a DC voltage shift in said power supply cable.

25. The apparatus according to claim 24, wherein said additional means for generating a DC voltage shift comprise an asymmetrical passive rectifier circuit at a neutral point of said transformer.

26. The apparatus according to claim 24, wherein said additional means for generating a DC voltage shift comprise an asymmetrical active rectifier circuit.
